(19) United States
(12) Patent Application Publication
(10) Pub. No.: US 2016/0003688 A1
(43) Pub. Date: Jan. 7, 2016

(54) ARRANGEMENT FOR TESTING A DEVICE FOR PROTECTING AN ELECTRONIC COMPONENT AGAINST OVERHEATING AND PERTAINING METHOD

(71) Applicant: ZF FRIEDRICHSHAFEN AG, Friedrichshafen (DE)

(72) Inventor: Thomas Luber, Hahnbach (DE)

(21) Appl. No.: 14/776,179

(22) PCT Filed: Feb. 12, 2014
(86) PCT No.: PCT/EP2014/052687

§ 371 Date: Sep. 14, 2015

(30) Foreign Application Priority Data
Mar. 14, 2013 (DE) 10 2013 204 467.4

(51) Int. Cl. G01K 13/00; H02H 5/04; G01R 31/00

(52) U.S. Cl. CPC G01K 13/00; G01R 31/00; H02H 5/04

(57) ABSTRACT

The invention relates to an assembly and a method for testing a device in order to protect an electronic component against overheating, wherein the device comprises a temperature sensor that is in thermal connection with the electronic component, and a first control circuit for the electronic component (6), wherein the temperature sensor is electrically connected to the first control circuit. The assembly has a heating element that is thermally connected to the temperature sensor, which heating element can be activated by means of a second control circuit.

The present disclosure relates to a control device for a transmission in a vehicle, an accessory control device for a control device of this type, a control system for a transmission in a vehicle, and a method for assembling a control system for a transmission in a vehicle.

The present disclosure relates to an assembly for testing a device configured to protect an electronic component against overheating, as well as an associated method.

When operating integrated semiconductor circuits, at least a portion of the electrical power is converted to heat. In certain conditions—for example, when overloaded, in the event of a short circuit, or external heating of the semiconductor chip—this can lead to an undesired excess temperature. In order to detect this excess temperature, and to protect the integrated semiconductor circuits, these circuits typically have a thermal protection device. This must suffice, however, for a variety of demands.

With circuit assemblies having a circuit breaker configured for switching loads, such as a DC motor, for example, an induction motor, or the like, a short circuit may occur in the load circuit, which may result in damage to the circuit breaker, or even the load that is to be switched. In order to protect it, the circuit breaker is provided with one or more temperature sensors, the signals from which are evaluated by an evaluation circuit, and which switch off the circuit breaker in the event of a short circuit that causes an acute rise in temperature in the circuit breaker. When a predefined thermal threshold value has been exceeded, the circuit breaker is switched off, and is thus protected from damage. The temperature sensors, typically designed as resistors, diodes, or transistor sensors, are preferably integrated here in the vicinity of the corresponding hot-spot, i.e. thus in the vicinity of the hottest point in the circuit breaker. The signal from the temperature sensor is then processed by an evaluation circuit, such that the switching off of the circuit breaker, or at least a reduction in power, occurs as soon as the temperature present at the temperature sensor exceeds a predefined temperature threshold value, which depends on the respective application and typically lies above 150° C.

An assembly for protecting an integrated circuit against excess temperature is known from DE 101 07 386 C1, having at least one detection device, which recognizes a malfunction in the integrated circuit, having at least one temperature sensor, which registers the temperature of at least a part of the integrated circuit, and having a logic device, which determines a malfunctioning in accordance with a detected malfunction and/or the detected temperature, and assigns a first temperature switching step HTL to the temperature sensor when functioning normally, and assigns the temperature sensor a second, lower temperature switching step when the circuit is malfunctioning. Furthermore, an integrated circuit having an assembly of this type, as well as a method for protecting an integrated circuit against excess temperatures, is known from DE 101 07 386 C1.

A circuit assembly for protecting a circuit breaker from overheating is known from EP 0 208 970 B1. To protect the power MOSFET in the event of excess temperature, a second semiconductor body is glued onto a semiconductor body containing the power MOSFET, which contains a temperature sensor circuit and a semiconductor switch. The two semiconductor bodies are in thermal contact with one another, such that an excess temperature within the semiconductor body of the power MOSFET can be detected in the temperature sensor circuit. The electronic switch, e.g. a thyristor, inside the second semiconductor body is inserted between the source electrode and the drain electrode of the power MOSFET. If the temperature inside the MOSFET increases due to an overload or excessive environmental temperatures, the electronic switch contained in the second semiconductor body short circuits the gate electrode for the source electrode of the MOSFET, such that the voltage previously present in the switched on state, between the source electrode and the gate electrode of the MOSFET, fails, and the MOSFET is switched off.

The disadvantage with the circuit assemblies known from the prior art is that the functioning of the temperature sensor cannot be tested in normal operation.

The object of the disclosed assembly is to provide a circuit with which it is possible to test a temperature sensor and a circuit connected to the temperature sensor, in order to protect an electronic component from overheating. A further object is to provide a method for this.

These objects shall be achieved with the assembly according to the features of the effective independent Claim 1, as well as the features of the effective Claim 4. Advantageous designs of the embodiments are the subject matter of dependent Claims.

The disclosure is based on an assembly for protecting an electronic component against overheating. The electronic component can be a part of a control device, for example, such as a transmission control device for a vehicle. This assembly comprises a temperature sensor, which is in thermal contact, or connection, with the electronic component. This thermal connection can be implemented, for example, in that the temperature sensor is attached to the electronic component by means of a thermally conductive adhesive. The electronic component can also be a semiconductor body attached to a printed circuit board, wherein the temperature sensor can then also be in thermal connection or thermal contact with the printed circuit board. Moreover, an electronic component is thus understood to be, on one hand, any type of heat generating semiconductor body, e.g. an integrated circuit or transistor, as well as a carrier plate, e.g. a printed circuit board, supporting this semiconductor body.

The electronic component is connected to a first control circuit. This control circuit can be a microcontroller, which substantially controls the current and voltage supply for the electronic component. The control circuit can, however, also receive and process signals and/or data generated by the electronic component. The temperature sensor is electrically connected to the first control circuit. It is thus possible for the first control circuit to receive and process signals and data from the temperature sensor.

According to the disclosure, there is a heating element present, which is thermally connected to the temperature sensor. The thermal connection can, for example, be achieved through the use of a thermally conductive adhesive, by means of which the heating element is attached to the temperature sensor. It is also possible, however, for the heating element to be integrated in the temperature sensor. The heating element is connected to a second control circuit. This second control circuit controls the current and voltage supply for the heating element.

In a preferred embodiment, there is a means for storing the heating curve of the temperature sensor. For practical purposes, the first control circuit is configured such that the temperature dependent signals transmitted from the temperature sensor to the first control circuit can be stored.

In a further preferred embodiment, there is a means for checking the switching state of the electronic component. For practical purposes, the first control circuit is configured such that the operating state of the electronic component can be determined.

The method according to the disclosed embodiments for testing a device to protect an electronic component against overheating comprises the following steps:

a) providing a device for protecting an electronic component, wherein the device comprises a temperature sensor and a temperature sensor having a thermal connection to the electronic component,

b) providing a heating element having a thermal connection to the temperature sensor,

c) heating the temperature sensor to a target temperature by means of the heating element,

d) comparison of the target temperature and the actual temperature of the temperature sensor,

e) switching the electronic component off when the actual temperature of the temperature sensor exceeds the target temperature.

The heating of the temperature sensor to a target temperature in step d) can occur, conveniently, during the operation of the electronic component. The steps c), d) and e) can occur at different time intervals during the operation of the circuit or electronic component that is to be monitored for overheating. As a matter of course, the steps can also occur at the start-up procedure for the electronic component, or in other words, when switching the electronic component on.

The embodiments shall be explained in greater detail below, based on the figures.

Therein:

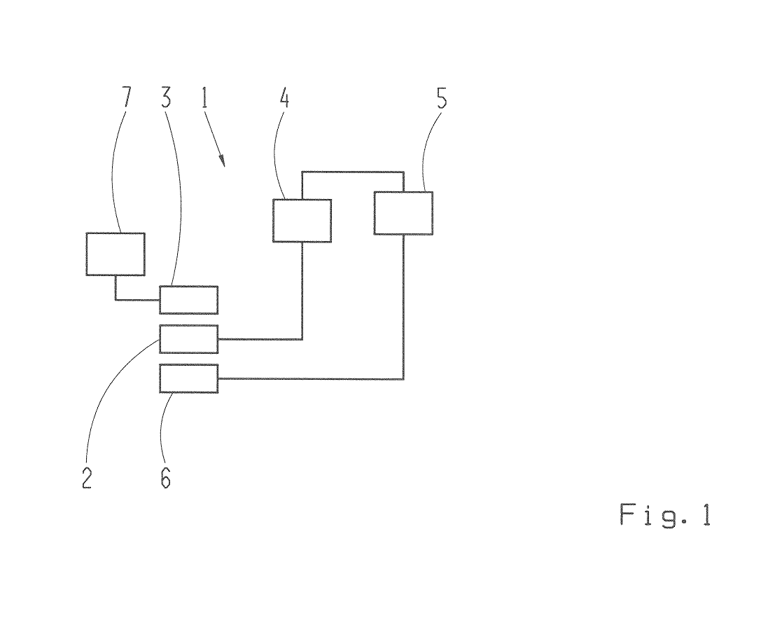

FIG. 1 shows a block diagram of the assembly having an overheating protection,

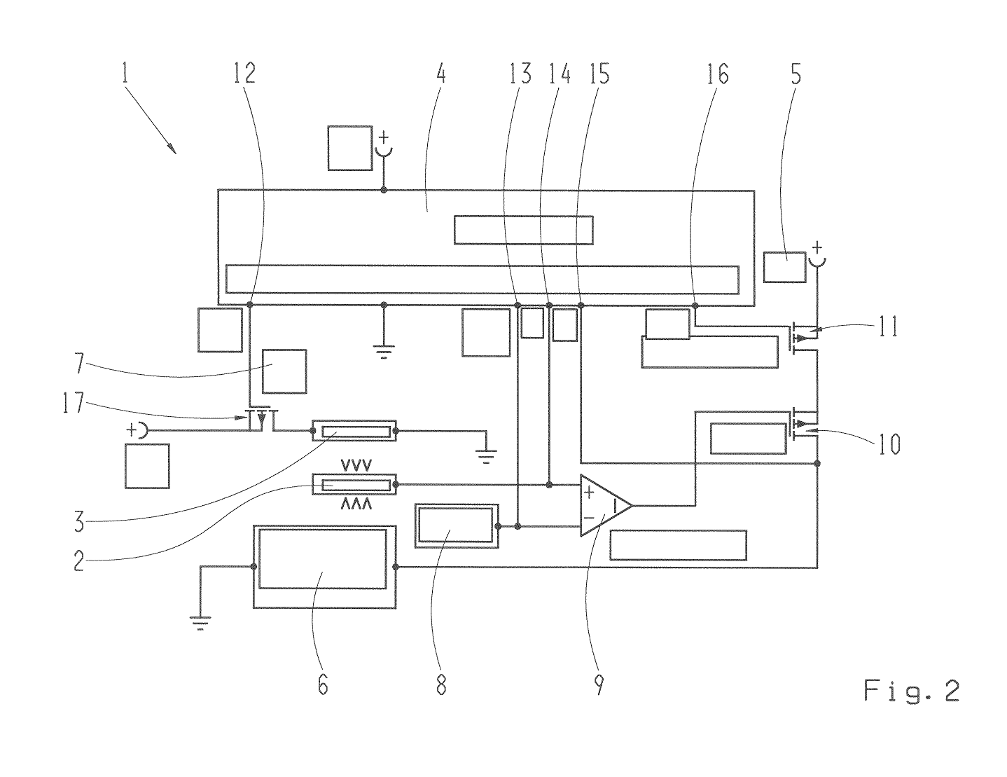

FIG. 2 shows a generalized embodiment of a temperature protection circuit.

FIG. 1 shows a block diagram of the assembly, having an assembly for protecting the circuit assembly against overheating. The circuit assembly is indicated with the numeral 1 in FIG. 1. The circuit assembly 1 has an electronic component 6. This electronic component 6 is, e.g., a power switch or a semiconductor element, which generates heat when in operation, through power dissipation. As a matter of course, the electronic component 6 can also be a printed circuit board having numerous electronic components 6.

The circuit assembly 1 has a temperature sensor 2 in the immediate proximity, which, for practical purposes, is in direct thermal connection with the electronic component 6. This temperature sensor 2 is attached to the electronic component 6 by means of a thermally conductive connection, e.g., by means of a thermally conductive adhesive. It is also possible, however, for the temperature sensor 2 to be disposed inside the electronic component 6, or in other words, is integrated in the electronic component 6.

Furthermore, the circuit assembly 1 has a first control circuit 4. This first control circuit 4 is connected to the temperature sensor 2. The control device is furthermore connected to the current and voltage supply 5 for the electronic component 6. The control device 4 is designed thereby, such that the temperatures measured by the temperature sensor 2 can be stored. Furthermore, the control device 4 is designed such that the current and voltage supply 5 for the electronic component 6 is interrupted when the measured temperature exceeds a predefined threshold value, and thus a further overheating of the electronic component 6 is prevented.

The circuit assembly 1 has, furthermore, a heating element 3, which is in thermal contact with the temperature sensor 2. This heating element 3 can also be integrated in the temperature sensor 2. It is also possible for the heating element 3, the temperature sensor 2 and the electronic component 6 to be integrated in a single component.

The heating element 3 is connected to a second control circuit 7. This second control circuit 7 is designed such that the heating element 3 is supplied with current and voltage. The second control circuit 7 and the first control circuit 4 can form, for practical purposes, a single control device.

FIG. 2 shows a generalized exemplary embodiment of a temperature protection circuit, the construction and functioning of which shall be described in greater detail.

The construction corresponds substantially to the construction from FIG. 1, wherein a heating element 3 is in thermal contact with a temperature sensor 2, wherein the latter, in turn, is in thermal contact with an electronic component 6.

The temperature sensor 2 measures the temperature of the electronic component 6, e.g. a power switch, which increases as a result of its own heat, or external heat. The comparator 9 compares the temperature of the temperature sensor 2 with a threshold value, e.g. 130° C., of a threshold value transmitter 8. This threshold value transmitter 8 can also be integrated in the control device 4. If the temperature exceeds the threshold value, the comparator 9 switches the power switch 6 off via the transistor 10, and protects the circuit 1 from overheating. The switch 6 can subsequently cool off, until the temperature of the temperature sensor 2 again falls below the threshold value of the threshold value transmitter 8. The comparator 9 then switches the power switch 6 back on via the transistor 10. The switching off occurs thereby such that the current and voltage supply 5 to the power switch 6 is interrupted.

The comparator 9 typically has a hysteresis.

The current temperature and the switching threshold can be measured via the analog/digital converter inputs 13 and 14 on the first control circuit 4, which, e.g., is a microcontroller. The microcontroller 4 can then check, via the analog/digital converter input 15 of the microcontroller 4, whether the power switch 6 is switched off. If not, the microcontroller 4 can also switch off the power switch 6 via the transistor 11.

The switching off of the power switch 6 is triggered via the second control circuit 7 for the heating element 3. In FIG. 2 the second control circuit 7 is integrated in the first control circuit 4, the microcontroller. The output 12 of the microcontroller 4 controls the transistor 17, which in turn switches on the heating element 3. This heating element 3 heats the temperature sensor 2 to a predefinable temperature, e.g. 130° C. If the comparator 9 detects that the temperature of the temperature sensor 2 has exceeded the threshold value for the threshold value transmitter 8, then the comparator 9 switches the power switch 6 off via the transistor 10. The switching off can be controlled with the analog/digital converter input 15 on the microcontroller 4. If it is detected, via the input 15, that the power switch 6 is not switched off, the current and voltage supply 5 for the power switch 6 can also be switched off, as described above, via the output 16 on the microcontroller 4 and the transistor 11.

The heating curve of the temperature sensor 2 when the heating element 3 is switched on can be recorded via the input 14 on the microcontroller 4, and checked for plausibility. By way of example, it can be checked whether the temperature sensor 2 has reached a certain temperature within a defined time period.

### REFERENCE SYMBOLS

1 circuit assembly

2 temperature sensor

3 heating element

4 first control device

5 current and voltage supply

6 electronic component

7 second control device

8 threshold value transmitter

9 comparator

10 transistor

11 transistor

12 output control device for heating element

13 input first control device to threshold value transmitter

14 input first control device to temperature sensor

15 check input

16 output switch off

17 transistor

1. An assembly for testing a device in order to protect an electronic component against overheating, wherein the assembly comprises:
a temperature sensor in thermal connection with the electronic component;
a first control circuit for the electronic component, wherein the temperature sensor is electrically connected to the first control circuit; and
a heating element in thermal connection with the temperature sensor, wherein the heating element can be controlled by a second control circuit.

2. The assembly according to claim 1, wherein the assembly is configured to store the heating curve of the temperature sensor.

3. The assembly according to claim 1, wherein the first control circuit is configured to check the switching state of the electronic component.

4. A method for testing a device in order to protect an electronic component against overheating, comprising the following steps:
providing a device for protecting an electronic component, wherein the device comprises a temperature sensor and a temperature sensor having a thermal connection with the electronic component,
providing a heating element that is in thermal connection with the temperature sensor,
heating the temperature sensor to a target temperature by means of the heating element,
comparing the target temperature and the actual temperature of the temperature sensor, and
switching the electronic component off when the actual temperature of the temperature sensor exceeds the target temperature.

5. The method according to claim 4, wherein the electronic component is operated by a first control circuit.

6. The method according to claim 5, wherein the temperature sensor is electronically connected to the first control circuit.

7. The method according to claim 5, wherein the heating element is operated by a second control circuit.

8. The method according to claim 4, the method further comprising storing the heating curve of the temperature sensor.

9. The method according to claim 4, the method further comprising checking the switching state of the electronic component.

10. An assembly for testing the operation of a temperature sensor, the assembly comprising:
an electronic component in thermal connection with the temperature sensor;
a first control circuit electrically connected to the temperature sensor, wherein the first control circuit is configured to control the electronic component;
a heating element in thermal connection with the temperature sensor, wherein a second control circuit is configured to control the heating element.

11. The assembly according to claim 10, wherein the assembly is configured to store the heating curve of the temperature sensor.

12. The assembly according to claim 10, wherein the first control circuit is configured to check the switching state of the electronic component.

13. The assembly according to claim 10, wherein the temperature sensor is connected to the heating element with a thermally conductive adhesive.

14. The assembly according to claim 10, wherein the heating element is integrated in the temperature sensor.

15. The assembly according to claim 10, the assembly further comprising a comparator configured to turn off the electronic component when the temperature sensor reaches a threshold value.

16. The assembly according to claim 15, wherein the comparator comprises a hysteresis.
